(19) United States
(12) Patent Application Publication
(10) Pub. No.: US 2013/0026546 A1
(43) Pub. Date: Jan. 31, 2013

(54) INTEGRATED CIRCUIT COMPRISING AN ISOLATING TRENCH AND CORRESPONDING METHOD

(71) Applicants: Laurent Favennec, Villard Bonnot (FR); Arnaud Tournier, Grenoble (FR); François Roy, Seyssins (FR)

(72) Inventors: Laurent Favennec, Villard Bonnot (FR); Arnaud Tournier, Grenoble (FR); François Roy, Seyssins (FR)

(73) Assignee: STMicroelectronics (Crolles 2) SAS, Crolles (FR)

(21) Appl. No.: 13/560,413

(22) Filed: Jul. 27, 2012

(30) Foreign Application Priority Data
Jul. 27, 2011 (FR) 11/56861

(51) Int. Cl. H01L 29/78; H01L 21/336

(52) U.S. Cl. 257/288; 438/299; 257/E29.255; 257/E21.409

(57) ABSTRACT

An integrated circuit including at least one isolating trench that delimits an active area made of a monocrystalline semiconductor material, the or each trench including an upper portion including an insulating layer that encapsulates a lower portion of the trench, the lower portion being at least partly buried in the active area and the encapsulation layer including nitrogen or carbon.

### CROSS REFERENCE TO RELATED APPLICATIONS

This application claims the priority benefit of French patent application number 1156861, filed on Jul. 27, 2011, which is hereby incorporated by reference to the maximum extent allowable by law.

### BACKGROUND

1. Technical Field

The present disclosure relates to the field of integrated circuits. More especially, it relates to integrated circuits comprising isolating trenches that each delimit an active area made of a semiconductor material as well as the corresponding method for making them.

2. Description of the Related Art

The production of MOS transistors with a high-permittivity dielectric gate is known. Integrating a layer configured to adjust the work function of a gate into a gate of such a MOS transistor is also known.

FIGS. 1, 1AA and 1BB are, respectively, a top view, a cross-sectional view along plane AA in FIG. 1 and a cross-sectional view along plane BB in FIG. 1 of a MOS transistor 1 produced on and in a portion of a semiconductor substrate 2.

Substrate 2 comprises an isolating trench 4, commonly referred to as Shallow Trench Isolation (STI) that delimits an active area 6 made of monocrystalline silicon. On the front face 7 of substrate 2, there is a gate 8 that is isolated from the substrate by an insulating interface layer 10 made of silica. Gate 8 successively comprises a high-permittivity dielectric layer 12 made of hafnium oxide placed on layer 10, a lanthanum or magnesium layer 14 adapted in order to adjust the work function of the gate, a metal layer 16 made of titanium nitride and, finally, layer 18 made of polycrystalline silicon. Two spacers 20 are located on either side of gate 8.

In an effort to simplify the drawings, the source and drain areas of transistor 1 are not shown.

Once layer 14 has been formed, the lanthanum present in this layer 14 tends to diffuse during each of the subsequent steps that requires a certain thermal budget. The Applicant has, in particular, noted the occurrence of this diffusion phenomenon at a temperature of approximately 500° C. The lanthanum has a tendency to be absorbed by the oxygen reservoirs and to form compounds of the La₂O₃ or lanthanum silicate type. The concentration of lanthanum in layer 14 diminishes in an uncontrolled manner. This layer is therefore unable to continue fulfilling its function: this falsifies adjustment of the work function of the gate. Because the threshold voltage of a MOS transistor is proportional, in particular, to the work function of its gate, the operating characteristics of the transistor are thus modified and are no longer controlled.

The same applies if layer 14 comprises magnesium rather than lanthanum. The magnesium diffuses and seeks out oxygen reservoirs in order to form MgO type compounds.

The Applicant has also noticed this same affinity with oxygen when the lanthanum and magnesium are deposited respectively in the form of La₂O₃ and MgO.

### SUMMARY

One aspect of one embodiment is to provide an integrated circuit comprising an isolating trench that avoids some of the drawbacks of previous integrated circuits.

One more particular aspect of one embodiment is to provide an integrated circuit comprising MOS transistors having a controlled gate work-function.

Another aspect of one embodiment is to provide a method for manufacturing an integrated circuit that mitigates at least some of the drawbacks of previous fabrication methods.

Thus, one embodiment makes provision for an integrated circuit comprising at least one isolating trench that delimits an active area made of a monocrystalline semiconductor material, further comprising at least one MOS transistor gate that is isolated from the active area by a gate insulation layer, upon which is successively deposited:

a layer comprising lanthanum, magnesium, aluminum or dysprosium, said layer being configured to adjust the work function of the gate,

and a metal layer,

the or each trench comprising an upper portion comprising an insulating layer that encapsulates a lower portion of the trench, the lower portion being at least partly buried in the active area and the encapsulation layer comprising nitrogen or carbon.

In another embodiment, the encapsulation layer comprises silicon oxynitride or silicon nitride.

In another embodiment, the encapsulation layer comprises silicon oxycarbide or silicon carbide.

In another embodiment, the encapsulation layer comprises two protruding elements arranged around the periphery of the layer.

One embodiment also makes provision for a method for manufacturing an integrated circuit in a monocrystalline semiconductor substrate, the said circuit comprising at least one MOS transistor gate, that is isolated from the active area by a gate insulation layer, upon which to is successively deposited:

a layer comprising lanthanum, magnesium, aluminum or dysprosium, said layer being configured to adjust the work function of the gate,

and a metal layer,

said method involving the following steps:

forming, in the substrate, at least one lower portion of an isolating trench that delimits an active area;

forming an insulating encapsulation layer comprising nitrogen or carbon with the insulating layer defining an upper portion of the isolating trench.

In another embodiment, the method also involves the following successive steps: forming a gate insulation layer;

forming a layer configured to adjust the work function of the gate; and forming a layer of conductive material;

In another embodiment, the method also involves the following steps:

forming source and drain areas on either side of the gate.

In another embodiment, the insulating encapsulation layer is formed after the following steps:

depositing a layer comprising nitrogen or carbon;

performing photolithography; and

partially etching the layer comprising nitrogen or carbon.

In another embodiment, the insulating encapsulation layer is formed after a nitrogen or carbon ion implantation step.

In another embodiment, forming the insulating encapsulation layer of the isolating trench involves the following steps:

forming the encapsulation layer by depositing a compliant layer comprising nitrogen or carbon;

forming an insulating layer by depositing it on the encapsulation layer; and

completely etching the insulating layer and the encapsulation layer so that part of the encapsulation layer covers the lower portion of the trench.

### BRIEF DESCRIPTION OF THE DRAWINGS

These aspects, characteristics and advantages as well as others will be explained in detail in the following description of the particular embodiments, given merely by way of example and not limitatively, reference being made to the enclosed drawings wherein:

Previously described FIGS. 1, 1AA and 1BB are, respectively, a top view, a cross-sectional view along plane AA in FIG. 1 and a cross-sectional view along plane BB in FIG. 1 of a MOS transistor;

FIG. 2 is a cross-sectional view of an isolating trench in one embodiment;

FIG. 3 is a cross-sectional view of an isolating trench in another embodiment;

FIGS. 4A to 4F are cross-sectional views illustrating steps in the method for manufacturing an isolating trench according to one embodiment;

FIG. 4G is a cross-sectional view along plane BB of an isolating trench separating two distinct MOS transistors according to one embodiment;

FIG. 5 is a cross-sectional view of an integrated circuit in one embodiment.

### DETAILED DESCRIPTION

For the sake of clarity, identical elements are denoted by identical references in the various figures and, as is usual when representing integrated circuits, the various figures are not drawn to scale.

In FIGS. 1, 1AA and 1BB, note the presence of at least three oxygen reservoirs. The spacers made of silica constitute a first oxygen reservoir. During a step subsequent to the formation of gate 8 and spacers 20 which requires a thermal budget, the lanthanum or magnesium in layer 14 diffuses naturally towards the spacers. This diffusion phenomenon is accentuated because spacers 20 are in direct contact with layer 14. In order to overcome this drawback, the spacers are advantageously made of silicon nitride.

Similarly, insulating interface layer 10 made of silica constitutes a second oxygen reservoir. In order to attenuate the diffusion of the lanthanum or magnesium in layer 14 into layer 10, one advantageously forms an insulating interface layer comprising an SiOₓN₁₋ₓ type compound. x is preferably 0.1 to 0.5 and advantageously 0.1 to 0.2.

Isolating trench 4 formed from silica forms a third possible oxygen reservoir. As shown in FIG. 1BB, layer 14 is partly located above trench 4. This facilitates diffusion of the lanthanum or magnesium towards trench 4.

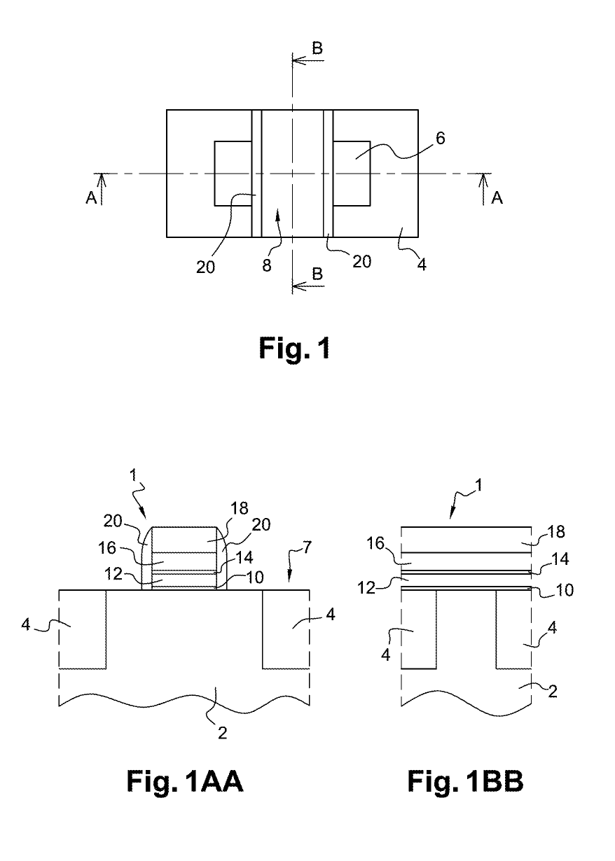

FIG. 2 is a cross-sectional view of an isolating trench 40 located in substrate 2 which is made of an advantageously monocrystalline semiconductor material, e.g., silicon.

Trench 40 comprises a lower portion 42 and an upper portion 44. On lower portion 42, made of silica for example, namely on the same side as the front face 7 of substrate 2, there is an insulating encapsulation layer for the trench, with the insulating layer forming the upper portion 44. In FIG. 2, the lower portion is buried in the substrate. Provision can be made for this portion 42 to be only partially buried. In other words, part of portion 42 can protrude relative to the substrate.

The Applicant has noted that the presence of nitrogen or carbon in layer 44 slows down the diffusion of the lanthanum or magnesium that is present in the gate towards the oxygen reservoir consisting of portion 42. The presence of nitrogen or carbon in layer 44 enables this layer to act as a shield between the gate and portion 42. This shield reduces the absorption of lanthanum or magnesium by portion 42 of trench 40. By way of example, layer 44 comprises silicon oxynitride (SiON) or silicon oxycarbide (SiOC). The higher the concentration of nitrogen (or carbon), the more effective the shield is. Advantageously, layer 44 comprises silicon nitride SiN (or silicon carbide SiC). Layer 44 has a thickness of 1 to 100 nm and preferably 2 to 10 nm.

By way of example, the method for forming layer 44 is as follows. One forms lower portion 42 of isolating trench 40 in substrate 2 by a photolithography process, followed by etching, followed by Chemical Vapor Deposition (CVD) of SiO₂. One then deposits an insulating layer comprising nitrogen (or carbon) over the entire front face 7 of substrate 2. This deposit can be obtained by CVD. Advantageously, deposition can be obtained by Low Pressure Chemical Vapor deposition (LPCV) or Rapid Thermal Chemical Vapor Deposition (RTCVD). One then performs a photolithography step followed by etching in order to leave only that part of the insulating layer that is near the lower portion 42 of isolating trench 40. One has thus formed insulating encapsulation layer 44.

This example of the method involves using a resin which has a polarity that complements that of the resin used in order to produce the lower portion of trench 40. This resin is relatively unsuitable for a cleanroom environment. Alternatively, one can also envisage using a second complementary mask (relative to the first mask that is used to form portion 42) but this involves additional cost. One should also note the possibility of a problem in obtaining alignment with portion 42.

Advantageously, the Applicant suggests the following structure.

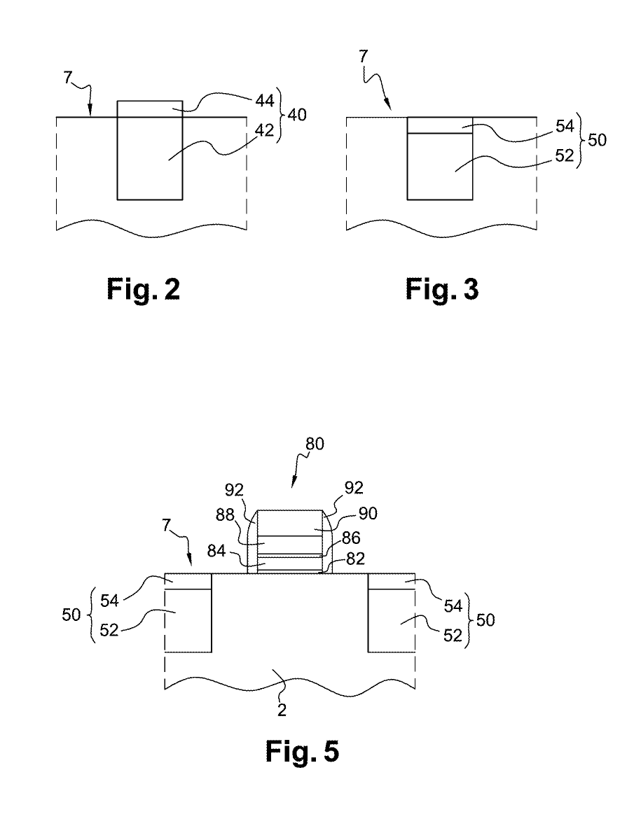

FIG. 3 is a cross-sectional view of isolating trench 50 located in substrate 2.

Trench 50 comprises a lower portion 52 and an upper portion 54. The lower portion is buried in the substrate. Portion 54 comprises an insulating encapsulation layer. Note that the upper surface of encapsulation layer 54 just substantially touches the upper surface of front face 7. Alternatively, one can make provision for the upper surface of trench 50 to be either recessed or protruding relative to the upper surface of the front face 7 of substrate 2.

Lower portion 52 comprises, for example, silica. Layer 54 comprises nitrogen (or carbon). It may also comprise an SiON (or SiOC) type compound. It is advantageously made of silicon nitride (or SiC). Layer 54 has a thickness of 1 to 100 nm and preferably 2 to 10 nm The presence of nitrogen (or carbon) in layer 54 limits the diffusion of lanthanum or magnesium towards the oxygen reservoir, namely towards lower portion 52.

One example of the method for producing layer 54 is as follows. One forms the isolating trench in substrate 2 (in the same way as one forms portion 42). After photolithography, one defines an opening at the level of the trench. One then performs nitrogen ion implantation in the silica that constitutes the trench. The implantation energy and quantity of dopants are chosen in order to form layer 54 on the surface in the upper portion of the trench. Layer 54 then constitutes a shield that prevents the lanthanum or magnesium from being absorbed in lower portion 52 of trench 50 which constitutes the oxygen reservoir.

During photolithography, there may be a problem in obtaining alignment of the resin relative to portion 52. Moreover, ion implantation may possibly cause damage to the active area.

The Applicant proposes the following method in order to improve the methods described above.

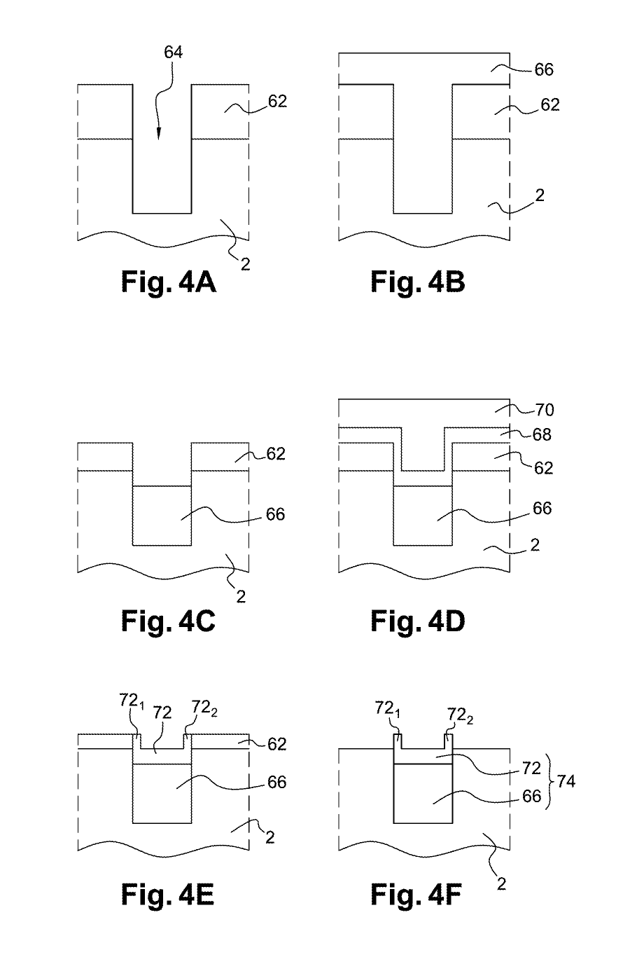

FIGS. 4A to 4F are cross-sectional views illustrating steps in an example of the method for manufacturing an isolating trench.

In FIG. 4A, an insulating layer 62 has been deposited on substrate 2, e.g., by using CVD. By way of example, layer 62 is made of SiO₂ and has a thickness of about 80 nm. One has then performed photolithography followed by etching in order to form a trench 64 in substrate 2.

In FIG. 4B, an insulating layer 66 has been deposited in order to fill trench 64. This deposit can be obtained by CVD. By way of example, layer 66 is made of silica. Alternatively, one can thermally grow silica on the two lateral flanks and the bottom of substrate 2 that are exposed following the etching step (described in relation to FIG. 4A). The purpose of this growth is to remedy any defects that appear after etching. By way of example, the layer obtained by growth is made of SiO₂ and has a thickness of about 0.4 nm. One then uses CVD to deposit silica in order to fill trench 64. One can then advantageously perform thermal annealing in order to densify the deposited oxide.

In FIG. 4C, a Chemical Mechanical Polishing (CMP) step has been performed. This polishing step stopped in layer 62. Layer 66 was then partially removed from trench 64 by cleaning using hydrofluoric acid for example. Wet etching of layer 66 stopped in trench 64. Alternatively, one can make provision to stop etching so that the upper surface of layer 66 just substantially touches the surface of the front face of substrate 2.

In FIG. 4D, an insulating layer 68 has been deposited on the front face of substrate 2. This layer is referred to as compliant and is a CVD or ALD (Atomic Layer Deposition) type layer. Layer 68 comprises nitrogen or carbon. Layer 68 has a thickness of about several nanometers. An insulating layer 70 has then been deposited, e.g., a CVD type layer. Layer 70 is made of SiO₂ for example.

In FIG. 4E, a second CMP step that stops in layer 62 has been performed. The remaining part of layer 68 forms encapsulation layer 72 for layer 66 located in the trench. Around the periphery of layer 72 and on its upper part, there are two protruding elements 72₁ and 72₂. These two elements, each forming a rib, are adjacent to layer 62. The remaining part of layer 70 has then been chemically etched, e.g. using hydrofluoric acid and phosphoric acid.

In FIG. 4F, the rest of layer 62 located on substrate 2 has been selectively etched. This then produces an isolating trench 74 comprising a lower portion 66 made of an insulating material buried in substrate 2 and encapsulated by the upper portion consisting of insulating layer 72 comprising nitrogen or carbon. The effect of the presence of the two protruding elements 72₁ and 72₂ is to extend the distance that the lanthanum or magnesium has to travel to reach the oxygen reservoir consisting of the lower portion 66 of isolating trench 74. Diffusion is therefore limited.

This increase in the distance separating the lanthanum or magnesium layer and the oxygen reservoir is best illustrated in FIG. 4G, which depicts a cross-sectional view of an isolating trench along plane BB, separating two distinct MOS transistors. Each protruding element 72₁ and 72₂ of a trench extends into the lower insulating layer 82 of a MOS transistor along the edges of the STI.

Alternatively, one can make provision to etch the two protruding elements of the encapsulation layer so that the upper surface of layer 72 just substantially touches the upper surface of substrate 2.

Alternatively, one can make provision to deposit or grow a layer of silica on substrate 2 before depositing layer 62 which can then be made of SiN. In fact, the CMP step (envisaged in FIG. 4C) stops more easily in an SiN layer than in an SiO₂ layer. Moreover, the layer of SiO₂ protects the silicon substrate during chemical etching of the SiN (using an H₃PO₄-based solution).

The nitrogen (or carbon) present in layer 72 significantly slows down the absorption of the lanthanum or magnesium in the lower portion 66 of the trench.

One can then form an isolated gate in substrate 2.

The three methods for forming the encapsulation layer for the lower portion of the trench are advantageously compatible with the CMOS methods used in microelectronics.

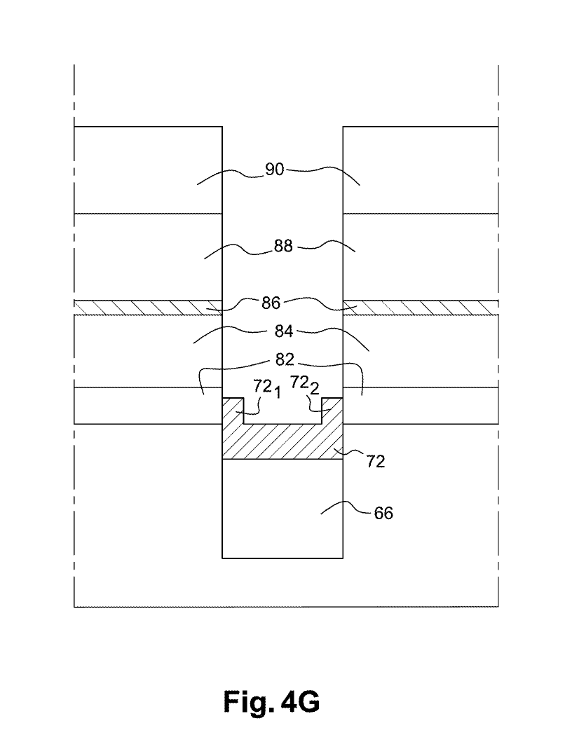

FIG. 5 is a cross-sectional view of an integrated circuit.

In substrate 2, there is an isolating trench 50. Alternatively, one can make provision to make an isolating trench 40, 74 or in accordance with the various embodiments described above. On the front face 7 of the substrate, namely in the active area delimited by the trench, there is a gate 80 of a MOS transistor. Gate 80 is insulated from the substrate by insulating interface layer 82 which comprises nitrogen, e.g. SiON. Alternatively, layer 82 may also comprise a bilayer comprising a layer of SiO₂ and a layer of SiON.

The gate comprises a high-permittivity dielectric layer 84 located on layer 82. By way of example but not limitatively, layer 84 is made of hafnium oxide, hafnium silicate or zirconium oxide. This layer 84 is advantageously formed by an ALD type process. The material of layer 84 is referred to as being of high permittivity because its dielectric constant is greater than the dielectric constant of the SiON and the SiO₂. A layer 86 of lanthanum, magnesium, aluminum or dysprosium is deposited on layer 84. This layer 86 is configured to adjust the work function of the gate. By way of example, layer 86 can be formed by Physical Vapor Deposition (PVD). To achieve this, one uses a target made of pure lanthanum or La₂O₃. Similarly, a target made of Mg or MgO is used in order to obtain a layer 86 made of magnesium. Alternatively, an ALD type process can be used.

The gate also comprises a metal layer 88 deposited, for instance, by a PVD type process. Layer 88 can be made of TiN, TaN or TaC. Finally, the gate comprises a layer 90 of polycrystalline silicon. One portion of layer 90 is intended to be silicided. On either side of gate 80 there are spacers 92 which are advantageously made of SiN. One then produces source and drain areas in order to obtain a MOS transistor.

This produces a transistor with optimized threshold voltage control. In fact, the constituents of layer 86 limit its diffusion towards the oxygen reservoirs constituted by spacers 92, interface layer 82 and isolating trenches 40, 50, 74.

Particular embodiments have been described. Various alternatives and modifications will be within the grasp of those skilled in the art. In particular, one can make provision for carrying out nitrogen ion implantation for insulating layer 68. Substrate 2 can be a Silicon On Insulator (SOI) type substrate.

Various embodiments with different alternatives are described above. Note that those skilled in the art will be able to combine various features of these various embodiments and alternatives without thereby showing any inventiveness. In particular, the methods intended to obtain the devices shown in FIGS. 2, 3 and 4F can be combined.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. Integrated circuit comprising at least one isolating trench that delimits an active area made of a monocrystalline semiconductor material, further comprising at least one MOS transistor gate that is isolated from the active area by a gate insulation layer, upon which is successively deposited:
a layer comprising lanthanum, magnesium, aluminum or dysprosium, said layer being configured to adjust the work function of the gate,
and a metal layer,
to the or each trench comprising an upper portion comprising an insulating layer that encapsulates a lower portion of the trench, the lower portion being at least partly buried in the active area and the encapsulation layer comprising nitrogen or carbon.

2. Integrated circuit as claimed in claim 1, wherein the encapsulation layer comprises silicon oxynitride or silicon nitride.

3. Integrated circuit as claimed in claim 1, wherein the encapsulation layer comprises silicon oxycarbide or silicon carbide.

4. Integrated circuit as claimed in claim 1, wherein the encapsulation layer comprises two protruding elements arranged around the periphery of the layer.

5. Method for manufacturing an integrated circuit in a monocrystalline semiconductor substrate, said circuit comprising at least one MOS transistor gate, that is isolated from the active area by a gate insulation layer, upon which is successively deposited:
a layer comprising lanthanum, magnesium, aluminum or dysprosium, said layer being configured to adjust the work function of the gate,
and a metal layer,
said method involving the following steps:
forming, in the substrate, at least one lower portion of an isolating trench that delimits an active area; and
forming an insulating encapsulation layer comprising nitrogen or carbon with the insulating layer defining an upper portion of the isolating trench.

6. Method as claimed in claim 5 which also involves the following successive steps:
forming a gate insulation layer;
forming a layer configured to adjust the work function of the gate; and
forming a layer of conductive material;

7. Method as claimed in claim 6 which also involves the following step:
forming source and drain areas either side of the gate.

8. Method as claimed in claims 5, wherein the insulating encapsulation layer is formed after the following steps:
depositing a layer comprising nitrogen or carbon;
performing photolithography;
partially etching the layer comprising nitrogen or carbon.

9. Method as claimed in claim 5, wherein the insulating encapsulation layer is formed after a nitrogen or carbon ion implantation step:

10. Method as claimed in claim 5, wherein formation of the insulating encapsulation layer of isolating trench involves the following steps:
forming the encapsulation layer by depositing a compliant layer comprising nitrogen or carbon;
forming an insulating layer by depositing it on the encapsulation layer;
forming etching the insulating layer and the encapsulation layer so that part of the encapsulation layer covers the lower portion of the trench.
